(19) United States
(12) Patent Application Publication
(10) Pub. No.: US 2025/0072142 A1
(43) Pub. Date: Feb. 27, 2025

(54) IMAGE SENSOR

(71) Applicant: SAMSUNG ELECTRONICS CO., LTD., Suwon-si (KR)

(72) Inventors: Gyunha PARK, Suwon-si (KR); JONGHYUN GO, Suwon-si (KR); JI-YOUN SONG, Suwon-si (KR); KEUN YEONG CHO, Suwon-si (KR)

(73) Assignee: SAMSUNG ELECTRONICS CO., LTD., Suwon-si (KR)

(21) Appl. No.: 18/677,417

(22) Filed: May 29, 2024

(30) Foreign Application Priority Data
Aug. 23, 2023 (KR) 10-2023-0110416

(51) Int. Cl. H01L 27/146

(52) U.S. Cl. CPC H01L 27/14623; H01L 27/14612; H01L 27/14636

(57) ABSTRACT

An image sensor may include: a pixel array in which a plurality of pixels are arranged in a matrix, including a first pixel and a second pixel disposed adjacent to each other, each of the plurality of pixels includes: at least one photoelectric conversion device; at least one floating diffusion region to which charges of the at least one photoelectric conversion device are configured to be transferred; a reset transistor configured to transfer a voltage at a reset node to the at least one floating diffusion region; a source follower transistor having one end connected to a pixel voltage node and configured to output a sampling voltage corresponding to charges of the at least one floating diffusion region; and a select transistor having one end connected to the source follower transistor and configured to output the sampling voltage to an output node.

### CROSS-REFERENCE TO RELATED APPLICATION(S)

This application claims priority under 35 USC § 119 to Korean Patent Application No. 10-2023-0110416, filed on Aug. 23, 2023, in the Korean Intellectual Property Office, the disclosure of which is herein incorporated by reference in its entirety.

### BACKGROUND

### 1. Field

Example embodiments relate to image sensors.

### 2. Description of Related Art

An image sensor is a semiconductor element converting an optical image into an electric signal. The image sensor may be classified into a charge-coupled device (CCD) image sensor and a complementary metal-oxide semiconductor (CMOS) image sensor.

The CMOS image sensor may be abbreviated as a CIS. The CIS may include a plurality of pixels arranged two-dimensionally. Each of the pixels may include, for example, a photodiode (PD) and pixel circuits connected to the photodiode PD.

Due to high performance and miniaturization of image sensors, pixel circuits are becoming finer.

### SUMMARY

Example embodiments provide an image sensor having high quality achieved by preventing coupling between components in pixel circuits.

According to an aspect of one or more example embodiments, an image sensor may include: a pixel array in which a plurality of pixels are arranged in a matrix, including a first pixel and a second pixel disposed adjacent to each other, each of the plurality of pixels includes: at least one photoelectric conversion device; at least one floating diffusion region to which charges of the at least one photoelectric conversion device are configured to be transferred; a reset transistor configured to transfer a voltage at a reset node to the at least one floating diffusion region; a source follower transistor having one end connected to a pixel voltage node and configured to output a sampling voltage corresponding to the charges of the at least one floating diffusion region; and a select transistor having one end connected to the source follower transistor and configured to output the sampling voltage to an output node. A shield doped with an impurity may be provided between the at least one floating diffusion region of the first pixel, and at least one of: a source node of the source follower transistor of the second pixel, the output node of the second pixel, and the pixel voltage node of the second pixel.

According to an aspect of one or more example embodiments, an image sensor may include: a pixel array in which a plurality of pixels are arranged in a matrix. The plurality of pixels may include a first pixel and a second pixel disposed adjacent to each other. Each of the first pixel and the second pixel may include at least one photoelectric conversion device, at least one floating diffusion region to which charges of the at least one photoelectric conversion device are configured to be transferred, a plurality of transistors, and a plurality of nodes. A shield doped with an impurity is disposed between the at least one floating diffusion region of the first pixel and at least one of the plurality of transistors and the plurality of nodes of the second pixel.

According to an aspect of one or more example embodiments, an image sensor may include: a plurality of pixels arranged in a matrix; and a plurality of stacked structures including a first structure and a second structure. Each of the plurality of pixels may include: photoelectric conversion devices provided at one of the plurality of stacked structures; at least one floating diffusion region to which charges provided to the at least one of the plurality of stacked structures are configured to be transferred; a plurality of transistors; and a plurality of nodes. The at least one floating diffusion region, the plurality of transistors, and the plurality of nodes are provided in the first structure, and the photoelectric conversion devices may be provided in the second structure. A shield formed by doping an impurity into a semiconductor substrate may be provided between two adjacent pixels of the plurality of pixels, and is configured to prevent coupling between the two adjacent pixels.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an image sensor according to example embodiments;

FIG. 2 is a circuit diagram of a pixel in an image sensor according to one or more example embodiments;

FIG. 3A is a conceptual diagram illustrating a layout of an image sensor according to one or more example embodiments;

FIG. 3B is a conceptual diagram illustrating a layout of an image sensor according to one or more example embodiments;

FIG. 4 is a plan view illustrating an image sensor according to one or more example embodiments;

FIG. 5A is a diagram illustrating first and second pixels adjacent to each other in a first direction within an image sensor;

FIG. 5B is a plan view illustrating a portion of components provided in a first structure of FIG. 4;

FIG. 5C is a plan view illustrating a portion of components provided in a second structure of FIG. 4;

FIG. 6 is a cross-sectional view taken along line A-A′ in FIG. 4;

FIG. 7A is a cross-sectional view taken along line A-A′ of FIG. 5A when a shield is not provided;

FIG. 7B is a cross-sectional view taken along line A-A′ of FIG. 5A when a shield is provided;

FIG. 8A is a cross-sectional view corresponding to line B-B′ of FIG. 5A when a shield is not provided;

FIG. 8B is a cross-sectional view corresponding to line B-B′ of FIG. 5A when a shield is provided;

FIG. 9 is a diagram illustrating first and second pixels adjacent to each other in a second direction within an image sensor;

FIG. 10A is a cross-sectional view taken along line C-C′ of FIG. 9A when a shield is not provided;

FIG. 10B is a cross-sectional view taken along line C-C′ of FIG. 9A when a shield is provided;

FIG. 11 is a diagram illustrating that a shield is formed to have a shape different from the shape in the above-described embodiment, in an image sensor according to one or more example embodiments;

FIG. 12 is a diagram illustrating that the shield is formed to have a shape different from the shape in the above-described embodiment, in an image sensor according to one or more example embodiments; and

FIG. 13 is a cross-sectional view illustrating an image sensor according to one or more example embodiments.

### DETAILED DESCRIPTION

The disclosure may be modified in various ways, and may have various embodiments, among which specific embodiments will be described in detail with reference to the accompanying drawings. However, it should be understood that the description of the specific embodiments of the disclosure is not intended to limit the disclosure to a particular mode of practice, and that the disclosure is to cover all modifications, equivalents, and substitutes included in the spirit and technical scope of the disclosure. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. Herein, when a term “same” or “equal” is used to compare a dimension of two or more elements, the term may cover a “substantially same” or “substantially equal” dimension.

Hereinafter, example embodiments will be described in detail with reference to the attached drawings. Like reference numerals in the drawings denote like elements, and redundant descriptions thereof will be omitted.

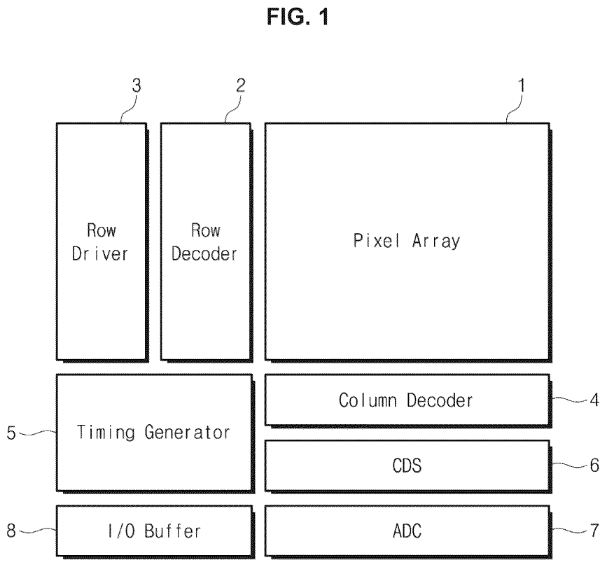

FIG. 1 is a block diagram of an image sensor according to one or more example embodiments.

Referring to FIG. 1, an image sensor according to one or more example embodiments may include a pixel array 1, a row decoder 2, a row driver 3, a column decoder 4, a timing generator 5, a correlated double sampler (CDS) 6, an analog-to-digital converter (ADC) 7, and an input/output (I/O) buffer 8.

The pixel array 1 may include a plurality of unit pixels arranged two-dimensionally, and may convert an optical signal into an electrical signal. The pixel array 1 may be driven by a plurality of driving signals such as a pixel select signal, a reset signal, and a charge transfer signal from the row driver 3. The converted electrical signal may be provided to the correlated double sampler 6.

The row driver 3 may provide a plurality of driving signals for driving a plurality of unit pixels to the pixel array 1, based on a result of decoding performed by the row decoder 2. When unit pixels are arranged in a matrix, driving signals may be provided for each row.

The timing generator 5 may provide timing signals and control signals to the row decoder 2 and the column decoder 4.

The correlated double sampler 6 may receive, hold, and sample an electrical signal generated by the pixel array 1. The correlated double sampler 6 may perform a double-sampling operation on a noise level and a signal level of the electrical signal to output a difference level corresponding to a difference between the noise level and the signal level.

The analog-to-digital converter 7 may convert analog signals, corresponding to the difference level output from the correlated double sampler 6, into digital signals and may output the digital signals.

The input/output buffer 8 may latch the digital signals, and may sequentially output the latched signals to an image signal processor based on a result of decoding performed by the column decoder 4.

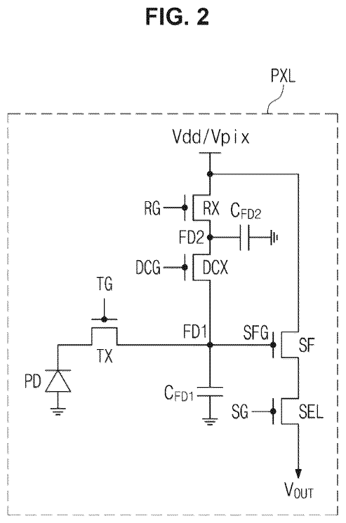

FIG. 2 is a circuit diagram of a pixel in an image sensor according to one or more example embodiments.

Referring to FIG. 2, a pixel PXL of an image sensor may include at least one photoelectric conversion device PD, at least one floating diffusion region to which the at least one photoelectric conversion device PD is transferred, a plurality of transistors, and a plurality of nodes. The floating diffusion region may selectively include a first floating diffusion region FD1 and a second floating diffusion region FD2. The pixel PXL may be or may correspond to the unit pixel of the pixel array 1 described above in reference to FIG. 1. According to one or more example embodiments, the floating diffusion region may include only the first floating diffusion region FD1 among the two floating regions FD1 and FD2. The transistors included in the pixel PXL may include a transfer transistor TD, a reset transistor RX, a source follower transistor SF, a select transistor SEL, and a dual conversion gain transistor DCX.

In the present embodiment(s), a single pixel PXL is described as including a single transfer transistor TX and a single photoelectric conversion device PD. However, the example embodiments are not limited thereto, and each pixel PXL may include two or more transfer transistors TX and/or two or more photoelectric conversion devices PD.

The photoelectric conversion device PD may generate and accumulate charges corresponding to incident light. The photoelectric conversion device PD may be, for example, a photodiode, a phototransistor, a photogate, a pinned photodiode PPD, or a combinations thereof.

The transfer transistor TX may be connected to the first floating diffusion region FD1 and may transfer the charges, accumulated in the photoelectric conversion device PD, to the first floating diffusion region FD1.

The first floating diffusion region FD1 may receive charges generated by the photoelectric conversion device PD and may cumulatively store the received charges. The source follower transistor SF may be controlled based on the amount of photocharges accumulated in the first floating diffusion region FD1.

The reset transistor RX may transfer a voltage at a reset node to at least one floating diffusion region, for example, the second floating diffusion region FD2. Charges, accumulated in the first floating diffusion region FD1 and the second floating diffusion region FD2, may be periodically reset based on a reset signal applied to a reset gate RG. A drain of the reset transistor RX may be connected to the dual conversion gain transistor DCX, and a source of the reset transistor RX may be connected to a pixel power supply voltage Vdd. In this case, the reset node may be or may not be the same as a pixel voltage node. In some embodiments, the reset node and pixel voltage node may be different from each other.

When the reset transistor RX and the dual conversion gain transistor DCX are turned on, the pixel power voltage Vdd may be transferred to the first and second floating diffusion regions FD1 and FD2. Accordingly, the charges accumulated in the first and second floating diffusion regions FD1 and FD2 may be discharged to reset the first and second floating diffusion regions FD1 and FD2.

The dual conversion gain transistor DCX may be connected between the first floating diffusion region FD1 and the second floating diffusion region FD2. The dual conversion gain transistor DCX may be connected in series to the reset transistor RX through the second floating diffusion region FD2. For example, the dual conversion gain transistor DCX may be connected between the first floating diffusion region FD1 and the reset transistor RX. The dual conversion gain transistor DCX may change first capacitance CFD1 of the first floating diffusion region FD1 in response to a dual conversion gain control signal to change a conversion gain of the pixel PXL.

For example, when an image is captured, low-illumination or high-illumination light may be incident on a pixel array, or high-intensity light or low-intensity light may be incident on the pixel array. Accordingly, a conversion gain of each pixel PXL may vary depending on the incident light. The dual conversion gain transistor DCX may be turned off and the pixel PXL may have a first conversion gain. The dual conversion gain transistor DCX may be turned on and the unit pixel PXL may have a second conversion gain, which is lower than the first conversion gain. For example, depending on the operation of the dual conversion gain transistor DCX, different conversion gains may be provided in a first conversion gain mode (or a high-illumination mode) and a second conversion gain mode (or a low-illumination mode), respectively.

When the dual conversion gain transistor DCX is turned off, capacitance of the first floating diffusion region FD1 may correspond to first capacitance CFD1. When the dual conversion gain transistor DCX is turned on, the first floating diffusion region FD1 may be connected to the second floating diffusion region FD2 and the capacitance may be a combination of the first capacitance CFD1 and the second capacitance CFD2 in the first and second floating diffusion regions FD1 and FD2. For example, when the dual conversion gain transistor DCX is turned on, the capacitance of the first or second floating diffusion region FD1 or FD2 may be increased to reduce the conversion gain. In addition, when the dual conversion gain transistor DCX is turned off, the capacitance of the first floating diffusion region FD1 may be reduced to increase the conversion gain.

The source follower transistor SF may have one end connected to a pixel voltage node, and may output a sampling voltage corresponding to a charge of the floating diffusion region FD. The source follower transistor SF may be a source follower buffer amplifier generating source-drain current in proportion to the amount of charges in the first floating diffusion region FD1 input to the source follower gate. The source follower transistor SF may amplify a change in potential in the first floating diffusion region FD1 and may output an amplified sampling voltage to an output line Vout through a select transistor SEL. A drain of the source follower transistor SF may be connected to the pixel power voltage Vdd, and a source of the source follower transistor SF may be connected to the select transistor SEL.

The select transistor SEL may be connected to the other end of the source follower transistor SF, and may output a sampling voltage to an output node. The select transistor SEL may select unit pixels in a pixel array (e.g., the pixel array 1 of FIG. 1) to be read in units of rows. When the select transistor SEL is turned on by a select signal applied to a gate of the select transistor, an electrical signal output to the source of the source follower transistor SF may be output to the output line Vout.

In one or more example embodiments, the pixel PXL may be implemented on at least one structure including a semiconductor substrate. One or more of the structure may be provided. When a plurality of the structures are provided, they may be sequentially stacked.

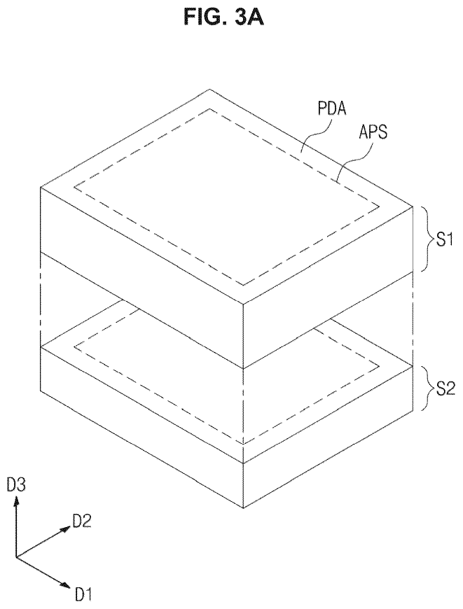

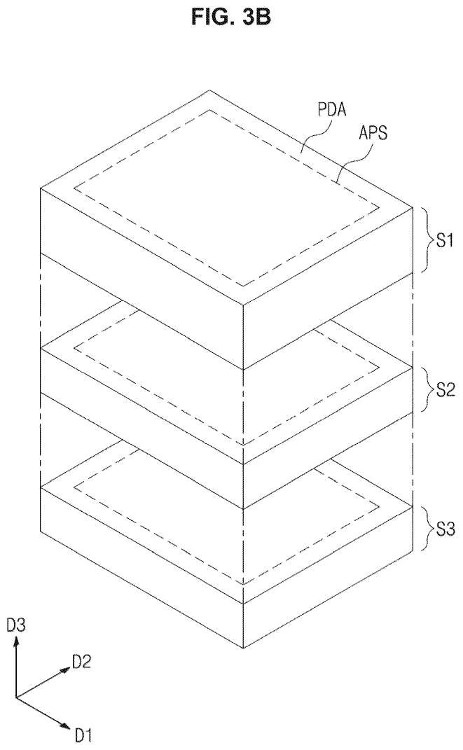

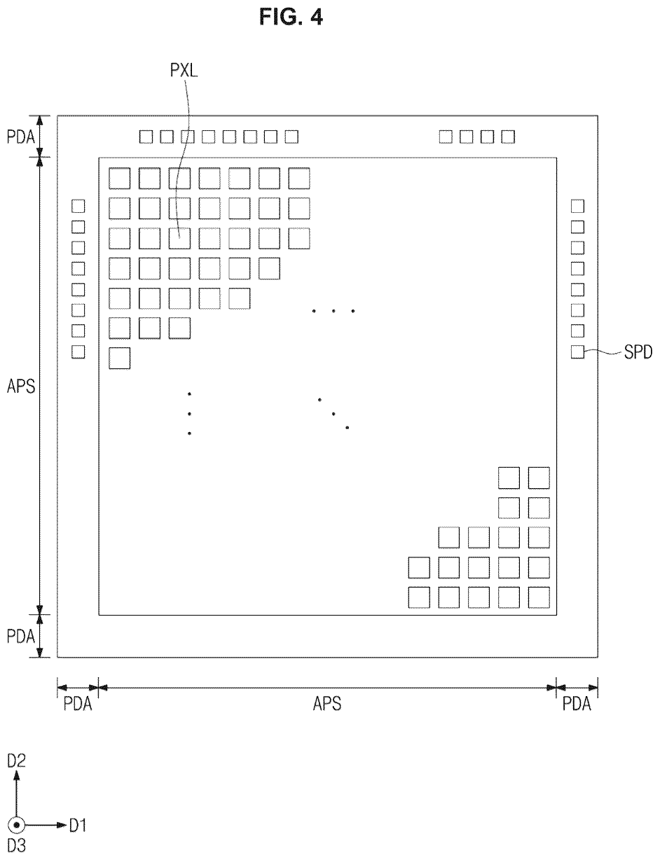

FIGS. 3A and 3B are conceptual diagrams, each illustrating a layout of an image sensor according to one or more example embodiments, and FIG. 4 is a plan view illustrating an image sensor according to one or more example embodiments.

Referring to FIGS. 3A, 3B, and 4, the image sensor may include a plurality of structures stacked in one direction. For example, the image sensor may include a first structure S1 and a second structure S2 stacked in a third direction D3, as illustrated in FIG. 3A. Alternatively, the image sensor may include first to third structures S1, S2, and S3 stacked in a third direction D3, as illustrated in FIG. 3B.

A plurality of structures (e.g. S1-S3) may constitute a chip, and may have the same size or different sizes. For example, an area of the first structure S1 may be smaller than an area of the second structure S2 and/or an area of the third structure S3, when viewed in plan view.

A bonding portion may be provided between two adjacent structures to bond the two structures to each other. Herein, a direction in which the second structure S2 and the first structure S1 are stacked is defined as a third direction D3 (a vertical direction in the drawings), and two directions intersecting each other on a plane perpendicular to the third direction D3 is defined as a first direction D1 and a second direction D2. However, in the present description, the first to third directions D1, D2, and D3 are relative directions set for ease of description and may be configured in different directions in one or more embodiments.

The first to third structures S1, S2, and S3 may include a pixel array region APS and a pad region PDA adjacent to the pixel array region APS. The pixel array region APS may be disposed in a central portion of the image sensor, when viewed in plan view. The pixel array region APS may include a plurality of pixels PXL.

Pixels PXL may output a photoelectric signal in response to receiving incident light. The pixels PXL may be arranged two-dimensionally in rows and columns. The rows may be parallel to the first direction D1, and the columns may be parallel to the second direction D2.

The pad region PDA may correspond to an edge portion of the image sensor. The pad region PDA may be provided in at least one of the first to third structures S1 to S3.

When viewed in plan view, the pad region PDA may surround the pixel array region APS. Signal pads SPD may be provided on the pad region PDA. The signal pads SPD may output electrical signals, generated from the pixels PXL, to an external device. Alternatively, an external electrical signal or voltage may be transmitted to the pixels PXL through the signal pads SPD. The pad region PDA is an edge region of the first semiconductor substrate 10, so that the signal pads SPD may be easily connected to the external device.

In example embodiments, components within a single pixel PXL may be provided in different structures and connected to each other. When a pixel PXL is provided to a plurality of stacked structures (for example, the first structure S1 and the second structure S2) a portion of the components may be provided in the first structure and remaining components may be provided in the second structure. For example, the photoelectric conversion device PD, the transfer transistor TX, and the first floating diffusion region FD1 may be provided in the first structure S1, and the remaining first and second floating diffusion regions FD1, FD2 and transistors (for example, the reset transistor RX, the source follower transistor SF, the select transistor SEL, and the dual conversion gain transistor DCX) may be provided in the second structure S2. The second structure S2 and/or the third structure S3 may be provided with a logic circuit that controls the pixels. The first floating diffusion region FD1 of the first structure S1 may be directly connected to the first floating diffusion region FD1 of the second structure S2 through an additional interconnection, and may correspond to the same node.

Logic circuits may include circuits for processing pixel signals from pixels PXL. For example, the logic circuits may include a control register block, a timing generator, a row driver, a readout circuit, a ramp signal generator, an image signal processor, or the like.

In one or more example embodiments, the second structure S2 and/or the third structure S3 may further include a memory device. The memory device may include a dynamic random access memory (DRAM) device, a static random access memory (SRAM) device, a spin-transfer torque magnetic random access memory (STT-MRAM) device, and a flash memory device, or the like, which may be embedded. An image sensor may temporarily store a frame image using such a memory device and may perform signal processing to significantly reduce Zello effect, resulting in improved operating characteristics of the image sensor. The memory device of the image sensor may include embedded logic devices to simplify a manufacturing process and to reduce a product size.

In one or more example embodiments, first and second floating diffusion regions FD1, FD2, the reset transistor RX, the source follower transistor SF, the select transistor SEL, the dual conversion gain transistor DCX, or the like, may be provided in the second structure S2, and the logic circuit may be provided in the third structure S3. In one or more example embodiments, a portion of first and second floating diffusion regions FD1, FD2, the reset transistor RX, the source follower transistor SF, the select transistor SEL, and the dual conversion gain transistor DCX may be provided in the second structure S2, and another portion of the first and second floating diffusion regions FD1, FD2, the reset transistor RX, the source follower transistor SF, the select transistor SEL, the dual conversion gain transistor DCX and the logic circuit may be provided in the third structure S3. Alternatively, in some embodiments, all of the first and second floating diffusion regions FD1, FD2, the reset transistor RX, the source follower transistor SF, the select transistor SEL, the dual conversion gain transistor DCX, or the like, and the logic circuit may be provided in the second structure S2.

Hereinafter, for ease of description, examples will be provided in which components of a pixel are provided in the first and second structures. Specifically, examples will be provided in which the photoelectric conversion device PD, the transfer transistor TX, and the first floating diffusion region FD1 are provided in the first structure S1, and first and second floating diffusion regions FD1, FD2, the reset transistor RX, the source follower transistor SF, the select transistor SEL, and the dual conversion gain transistor DCX are provided in the second structure S2.

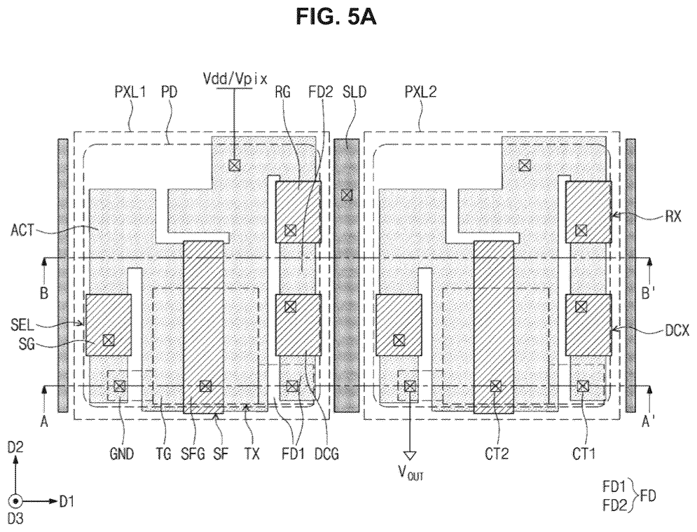

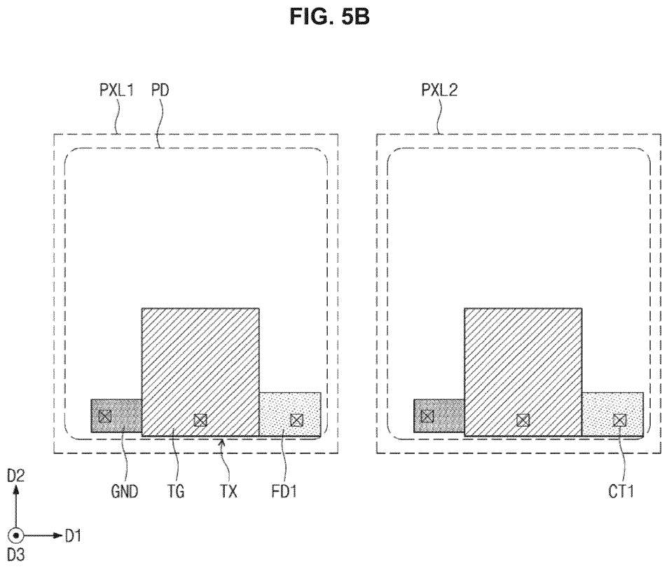

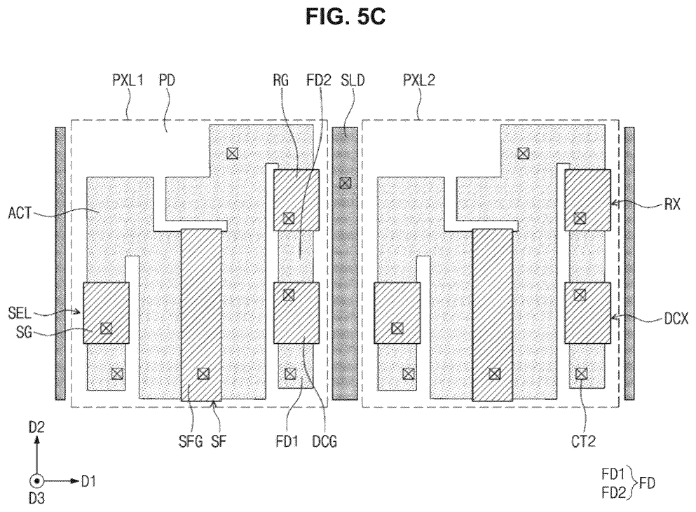

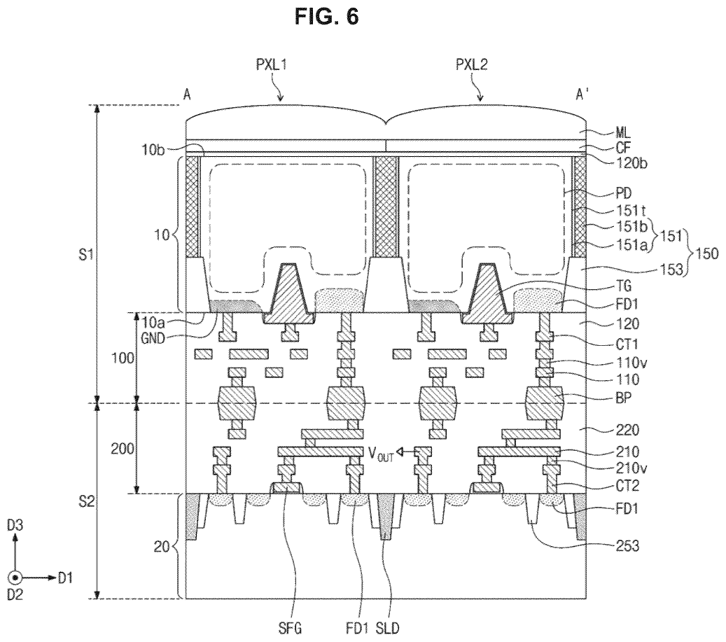

FIG. 5A is a diagram illustrating first and second pixels PXL adjacent to each other in the first direction D1 within the image sensor, FIG. 5B is a plan view illustrating a portion of components provided in the first structure S1 of FIG. 4, and FIG. 5C is a plan view illustrating a portion of components provided in the second structure S2 of FIG. 4. FIG. 6 is a cross-sectional view taken along line A-A′ in FIG. 4. For ease of description, transistors are mainly illustrated in FIGS. 5A to 5C. In FIG. 5A, components disposed in the first structure S1 are represented by solid lines, and components disposed in the second structure S2 are represented by dashed lines.

Referring to FIGS. 4, 5A to 5C, and 6, the image sensor according to one or more example embodiments may include first and second structures S1 and S2 stacked in the third direction D3. First structure S1 and a second structure S2 may be stacked in contact with each other, as shown in FIG. 6.

The first structure S1 may include a first semiconductor substrate 10 on which the photoelectric conversion device PD, the transfer transistor TX, and the first floating diffusion region FD1 are formed, a first conductive pattern 100 is provided on the first semiconductor substrate 10, a device isolation layer 150, a color filter CF, and a microlens ML. The first conductive pattern 100 may include first contacts CT1, respectively connected to components (for example, the transfer transistor TX, a ground region GND, or the like) provided on the first semiconductor substrate 10, and at least one layer of first interconnections 110 connected to the first contacts CT1. First vias 110v may be provided between the first contacts CT1, between the first interconnections 110, and between the first contacts CT1 and the first interconnections 110.

The second structure S2 may include a second semiconductor substrate 20, on which a plurality of transistors other than the photoelectric conversion device PD and the transfer transistor TX, a plurality of nodes, and a shield SLD are formed, and a second conductive pattern 200 provided on the second semiconductor substrate 20. The second conductive pattern 200 may include second contacts CT2, respectively connected to components (for example, a reset transistor RX, a source follower transistor SF, a select transistor SEL, a dual conversion gain transistor DCX, or the like) provided on the second semiconductor substrate 20, and at least one layer of second interconnections 210 connected to the second contacts CT2. Second vias 210v may be provided between the second contacts CT2, between the second interconnections 210, and between the second contacts CT2 and the second interconnections 210.

Each pixel PXL may include a photoelectric conversion device PD, one or more floating diffusion regions FD1 and FD2, transistors (a transfer transistor TX, a reset transistor RX, a source follower transistor SF, a select transistor SEL, and/or a dual conversion gain transistor DCX), and nodes connected to the transistors. A portion of the photoelectric conversion device PD, the transfer transistor TX, and the floating diffusion regions FD1 and FD2 may be provided in the first structure S1, and a portion of the floating diffusion regions FD1 and FD2 and the remaining transistors (the reset transistor RX, the source follower transistor SF, the select transistor SEL, and the dual conversion gain transistor DCX) may be provided in the second structure S2 and/or the third structure S3.

According to the present embodiment(s), the photoelectric conversion device PD, the first floating diffusion region FD1, the transfer transistor TX (provided in the first structure S1), and the reset transistor RX, the source follower transistor SF, the select transistor SEL, and the dual conversion gain transistor DCX (provided in the second structure S2), are provided in different structures when viewed in plan view, so that they may overlap each other. Therefore, in FIG. 5A, the components disposed in the first structure S1 are represented by dashed lines to be distinguished from the components disposed in the second structure S2.

In one or more example embodiments, the transistors provided on the second semiconductor substrate 20 may be n-channel metal-oxide semiconductor (NMOS) transistors, and a source and a drain of each transistor may be regions doped with second conductivity type impurities (e.g. N-type impurities). However, the transistors may be p-channel metal-oxide semiconductor (PMOS) transistors, and thus, locations of the source and drain of each transistor may vary.

The transistors of the second semiconductor substrate 20 may be connected to each other or external components through the second contacts CT2 and the second interconnections 210. For example, the second contact CT2 provided at the source follower gate SFG and the second contact CT2 provided at the first floating diffusion region FD1 may be connected to each other through the second interconnection 210 within a single pixel. A pixel voltage Vpix may be applied to a drain of the source follower transistor SF through the second contact CT2, and a pixel power supply voltage Vdd may be applied to a drain of the reset transistor RX through the second contact CT2. The pixel voltage Vpix and the pixel power supply voltage Vdd may be the same.

Hereinafter, specific examples of the first structure S1 will be described in detail, and then specific examples of the second structure S2 will be described.

In the first structure S1, the first semiconductor substrate 10 may have a first surface 10a and a second surface 10b opposing each other. The first surface 10a of the first semiconductor substrate 10 may be a front surface, and the second surface 10b may be a rear surface. Light may be incident on the second surface 10b of the first semiconductor substrate 10.

The first semiconductor substrate 10 may be, for example, a silicon substrate, a germanium substrate, or a silicon-germanium substrate. The first semiconductor substrate 10 may further include a group III element. The group III element may be an impurity having the first conductivity type. Accordingly, the first semiconductor substrate 10 may have the first conductivity type. For example, the first conductivity type impurities may include P-type impurities such as aluminum (Al), boron (B), indium (In), and/or gallium (Ga). In the following embodiments, the first conductivity type will be described as P-type. However, the first conductivity type may be N-type.

The first semiconductor substrate 10 may include the photoelectric conversion device PD, the transfer transistor TX, the first floating diffusion region FD1, and the ground region GND for each pixel PXL.

The photoelectric conversion devices PD may be interposed between the first surface 10a and the second surface 10b of the first semiconductor substrate 10. The photoelectric conversion devices PD may be doped regions containing impurities having the second conductivity type. In one or more example embodiments, the photoelectric conversion devices PD may include a group V element, and the group V element may be an impurity having the second conductivity type. The impurity having the second conductivity type may have a conductivity type, opposite to that of the impurity having the first conductivity type. Impurities having the second conductivity type may include N-type impurities such as phosphorus, arsenic, bismuth, and/or antimony.

A ground region GND may be formed in the first semiconductor substrate 10. The ground region GND may have a higher impurity concentration of the first conductivity type than the first semiconductor substrate 10. For example, the ground region GND may be an impurity region formed by heavily doping P-type impurities P⁺⁺ into the P-type first semiconductor substrate 10.

The first floating diffusion region FD1 may be formed in the first semiconductor substrate 10. The first floating diffusion region FD1 may be spaced apart from the photoelectric conversion device PD and the ground region GND. The first floating diffusion region FD1 may have the second conductivity type. For example, the first floating diffusion region FD1 may be an impurity region having the second conductivity type, formed by implanting N-type impurities into the P-type first semiconductor substrate 10.

In some embodiments, the first floating diffusion region FD1 may have the second conductivity type with a higher impurity concentration than the photoelectric conversion device PD. For example, the floating diffusion region FD may be formed by heavily doping N-type impurities N⁺ into the P-type first semiconductor substrate 10. A channel region may be formed between the photoelectric conversion device PD and the first floating diffusion region FD1.

The first contacts CT1, provided in the first floating diffusion region FD1 of the first structure S1, may be connected in series to the second contacts CT2 provided in the first floating diffusion region FD1 of the second structure S2 to be described later.

The transfer transistor TX may include a transfer gate TG forming a transfer channel between the photoelectric conversion device PD and the first floating diffusion region FD1, a gate insulating layer insulating the first semiconductor substrate 10 and the transfer gate from each other, and a gate spacer provided on a side surface of the transfer gate. The transfer gate TG may have a buried gate structure.

The transfer transistor TX may be connected to other components through first contacts CT1, which may be respectively connected to the transfer gate TG, the first floating diffusion region FD1, and the ground region GND. At least two layers of first interconnections 110 may be connected to the first contacts CT1, and first vias 110v may connect the first interconnections 110.

A first upper insulating layer 120 may be provided on the first surface 10a on which the transfer gate TG is formed. In one or more example embodiments, the first upper insulating layer 120 may have a single-layer structure or a multilayer structure and may include at least one of, for example, a silicon oxide, a silicon nitride, a silicon oxynitride, and a low-K dielectric material having a lower dielectric constant than the silicon oxide, but example embodiments are not limited thereto. For example, the first upper insulating layer 120 may include undoped silicate glass (USG).

The device isolation layer 150 may be provided between adjacent pixels PXL to separate pixels PXL from each other. For example, pixels PXL adjacent to each other may be separated by the device isolation layer 150. For example, the device isolation layer 150 may be provided along a periphery of the photoelectric conversion device PD when viewed in the plan view.

The device isolation layer 150 may include a first separation layer 151, surrounding the photoelectric conversion device PD, and a second separation layer 153, provided at a shallower depth than the first separation layer 151.

The first separation layer 151 may be formed within the first semiconductor substrate 10 to surround each of the pixels PXL. For example, the first separation layer 151 may be an insulating material buried in a deep trench 151t formed by patterning the first semiconductor substrate 10 (e.g. as deep trench isolation (DTI)). The deep trench 151t may penetrate the first semiconductor substrate 10. For example, the deep trench 151t may be provided to penetrate through the first surface 10a and the second surface 10b of the first semiconductor substrate 10.

In one or more example embodiments, the first separation layer 151 may include a conductive separation layer 151b, filled with a conductive material in the deep trench 151t, and an insulating liner 151a provided between the first semiconductor substrate 10 and the conductive separation layer 151b. The conductive separation layer 151b may include a crystalline semiconductor material (e.g. polysilicon). In one or more example embodiments, the conductive separation layer 151b may further include a dopant, and the dopant may include an impurity having the first conductivity type or an impurity having the second conductivity type. For example, the conductive separation layer 151b may include doped polysilicon. The conductive separation layer 151b may be applied with a negative voltage or a ground voltage to prevent dark current.

The insulating liner 151a may be provided along sidewalls of the deep trench 151t. The insulating liner 151a may be, for example, a silicon-based insulating material (for example, a silicon nitride (Si₃N₄), a silicon oxide or silicate (SiO₂), and/or a silicon carbon nitride (SiCN)), and/or a high-κ dielectric metal oxide (for example, a hafnium oxide (HfOx), a zirconium oxide (ZrO2), a titanium oxide (TiO₂), an aluminum oxide or alumina (Al₂O₃), or the like). The conductive separation layer 151b may be spaced apart from the first semiconductor substrate 10 by the insulating liner 151a. Accordingly, when the image sensor operates, the conductive separation layer 151b may be electrically separated from the first semiconductor substrate 10.

The second separation layer 153 may be provided in a shallow trench recessed from the first surface 10a by a predetermined depth when viewed in cross-section. Unlike the deep trench 151t, the shallow trench may be recessed from the first surface 10a of the first semiconductor substrate 10 only by the predetermined depth and may not penetrate through the first semiconductor substrate 10.

The second separation layer 153 may be provided on an edge directly adjacent to the floating diffusion region FD to prevent a defect caused by a combination of electrons in the floating diffusion region FD and holes accumulated on a side of the first separation layer 151 (e.g. dark current). When the first separation layer 151 is applied with a negative voltage, the dark current may be prevented. However, when the second separation layer 153 is not provided, holes accumulated adjacent to the first separation layer 151 may be strongly bound to the electrons of the floating diffusion region FD. Such an electron-hole binding pair may be moved to a photoelectric conversion region and cause a defect. To prevent the defect, the second separation layer 153 may be formed on an edge adjacent to the floating diffusion region FD to prevent electrons in the floating diffusion region FD from binding to holes near the second separation layer 153. For example, the second separation layer 153 may be formed only near the floating diffusion region FD, causing the electrons in the floating diffusion region FD to be spaced apart from the holes near the second separation layer 153. Accordingly, drain leakage in the floating diffusion region FD induced by the transmission gate TG (e.g. gate induced drain leakage (GIDL)) may be reduced.

For example, the second separation layer 153 may be provided as an insulating material buried in a shallow trench (e.g. as shallow trench isolation (STI)). The second separation layer 153 may be provided adjacent to the first surface 10a of the first semiconductor substrate 10. For example, the second separation layer 153 may extend from the first surface 10a of the first semiconductor substrate 10. In one or more example embodiments, the second separation layer 153 may have a multilayer structure. The second separation layer 153 may also include at least one of a silicon oxide, a silicon nitride, a silicon oxynitride, and combinations thereof, but example embodiments are not limited thereto. The first separation layer 151 may be provided below a region in which the second separation layer 153 is formed. For example, the first separation layer 151 and the second separation layer 153 may be provided to be vertically stacked on a circumference of a pixel adjacent to the floating diffusion region FD when viewed in cross-section.

A first lower insulating layer 120b may be provided on the second surface 10b. The first lower insulating layer 120b may cover the second surface 10b of the first semiconductor substrate 10 and may be provided to have a multilayer structure. The first lower insulating layer 120b may include, for example, a silicon-based insulating material such as a silicon oxide, a silicon nitride, and/or a silicon oxynitride.

The color filter CF may be provided on the first lower insulating layer 120b.

The color filter CF may be disposed for each pixel PXL on the second surface 10b of the first semiconductor substrate 10. For example, the color filters CF may be provided in locations corresponding to the photoelectric conversion devices PD, respectively. Each of the color filters CF may include one of a red filter, a blue filter, and a green filter, but example embodiments are not limited thereto and other color filters may be provided. The color filters CF may constitute color filter arrays. For example, the color filters CF may constitute arrays arranged in the first direction D1 and the second direction D2 when viewed in the plan view.

The microlens ML may be disposed on the second surface 10b of the first semiconductor substrate 10. For example, the microlens ML may be disposed on the color filter CF. The microlens ML may include a lens pattern and a planar portion. The planar portion of the microlens ML may be provided on the color filters CF. The lens pattern may be provided on the planar portion. The lens pattern may be integrated with the planar portion, and may be connected to the planar portion without an interface. The lens pattern may include the same material as the planar portion. For example, the planar portion may be omitted and the lens pattern may be disposed directly on the color filters CF.

The lens pattern may be hemispherical. The lens pattern may converge incident light. Lens patterns may be provided in locations corresponding to the photoelectric conversion devices PD of the first semiconductor substrate 10, respectively. For example, a lens pattern may be provided on a photoelectric conversion device PD in a first pixel region of the first semiconductor substrate 10.

The microlens ML may be transparent and may allow light to pass therethrough. The microlens ML may include an organic material such as polymer. For example, the microlens ML may include a photoresist material or a thermosetting resin.

A protective layer may be provided on the microlens ML. The protective layer may include an organic material and/or an inorganic material. According to one or more example embodiments, the protective layer may include a silicon-containing material such as silicon oxide, silicon nitride, silicon oxynitride, silicon carbide, silicon oxycarbide, silicon carbonitride, and/or silicon oxycarbonitride. Alternatively, the protective layer may include aluminum oxide, zinc oxide, and/or hafnium oxide. The protective layer may have insulating properties, but example embodiments are not limited thereto. The protective layer may allow light to pass therethrough.

In the second structure S2, the second semiconductor substrate 20 may be, for example, a silicon substrate, a germanium substrate, or a silicon-germanium substrate. The second semiconductor substrate 20 may further include a group III element. The group III element may be an impurity having the first conductivity type. Accordingly, the second semiconductor substrate 20 may have the first conductivity type.

In the second semiconductor substrate 20, each pixel PXL is provided with an active region ACT divided by a third separation layer 253 when viewed in the plan view. The active region ACT may be doped with impurities having the second conductivity type. In one or more example embodiments, the active region ACT may be doped with N-type impurities.

The third separation layer 253 may be an insulating material buried in a shallow trench (e.g. as shallow trench isolation (STI)). In one or more example embodiments, the third separation layer 253 may have a multilayer structure. The third separation layer 253 may also include at least one of a silicon oxide, a silicon nitride, a silicon oxynitride, and combinations thereof, but example embodiments are not limited thereto. The third separation layer 253 may be provided along a periphery of a single pixel PXL such that an active region ACT of the single pixel PXL is spaced apart from an active region ACT of an adjacent pixel PXL. In the present embodiment(s), the third separation layer 253 is illustrated as being provided on the second semiconductor substrate 20, but example embodiments are not limited thereto and the third separation layer 253 may be omitted. When the single pixel PXL has an area sufficient to separate the active region ACT, the third separation layer 253 may not be provided or may be provided only in a certain region.

A gate of each transistor may be provided on the active region ACT. In one or more example embodiments, a reset gate RG, a source follower gate, a select gate SG, and a dual conversion gain gate DCG may be provided on the active region ACT. Active regions ACT on opposite sides with respective gates of the transistors interposed therebetween may serve as a source or a drain.

In the present embodiment(s), the active region ACT disposed on one side of the dual conversion gain transistor DCX may correspond to the first floating diffusion region FD1, and the active region ACT disposed between the dual conversion gain transistor DCX and the reset transistor RX may correspond to the second floating diffusion region FD2. For example, the first floating diffusion region FD1 may be connected to a source of the dual conversion gain transistor DCX, and the second floating diffusion region FD2 may be connected to a drain of the dual conversion gain transistor DCX and a source of the reset transistor RX. A drain of the reset transistor RX may be connected to a drain of the source follower transistor SF. The drain of the reset transistor RX, the drain of the source follower transistor SF, and the active region ACT between the drain of the reset transistor RX and the source follower transistor SF may correspond to a reset node, receiving a reset voltage through the second contact CT2, and a pixel voltage node receiving a pixel voltage Vpix. A source of the source follower transistor SF may be connected to a drain of the select transistor SEL, and a source of the select transistor SEL may correspond to an output node outputting a sampling voltage through the second contact CT2.

A shield SLD may be provided between two adjacent pixels PXL, which will be further described later.

A second insulating layer 220 may be provided on transistors of the second semiconductor substrate 20. The second insulating layer 220 may have a multilayer structure.

A bonding portion may be provided at an uppermost portion (inverted to be illustrated as a lowermost portion in the drawing) of first interconnections 130 and an uppermost portion of second interconnections 230 to connect the first structure S1 and the second structure S2.

The bonding portion may include bonding pads BP disposed to face the first structure S1 and the second structure S2. The bonding pad BP may be formed of various conductive materials, capable of being bonded by heating, or the like, and may be integrated with the first structure S1 and the second structure S2 through bonding after fabrication of the first and second structures S1 and S2. The bonding pad BP may include a metal such as aluminum, copper, tungsten, titanium, tantalum, or alloys thereof. In one or more example embodiments, the bonding pad BP may be formed of copper, allowing the first and second structures S1 and S2 to be bonded through copper-copper bonding.

The first conductive pattern 100 of the first structure S1 and the second conductive pattern 200 of the second structure S2 may be connected to each other through the first interconnections 130, the bonding pads BP, and the second interconnections 230, allowing a pixel to be driven.

The image sensor according to one or more example embodiments having the above-described structure may include the shield SLD to prevent parasitic capacitance or junction capacitance from being formed due to coupling that may occur between nodes of two adjacent pixels.

The shield SLD may be provided between adjacent pixels PXL, and may be provided between a floating diffusion region FD of each pixel and pixels adjacent to the floating diffusion region FD of each pixel.

Hereinafter, for ease of description, two pixels PXL adjacent to each other in a first direction will be referred to as a first pixel PXL1 and a second pixel PXL2.

For example, the first pixel PXL1 may be provided between the floating diffusion region FD in the first pixel PXL1 and nodes of the second pixel PXL2 adjacent to the first pixel PXL1 to prevent coupling between the floating diffusion region FD in the first pixel PXL1 and the nodes of the second pixel PXL2. In one or more example embodiments, the nodes of the second pixel PXL2 may include, for example, a source node and an output node of the source follower transistor SF. The nodes of the second pixel PXL2 may include, for example, a source of the source follower transistor SF corresponding to the source node of the source follower transistor SF and a source of the select transistor SEL corresponding to the output node of the source follower transistor SF. Accordingly, the shield SLD may be provided to prevent the floating diffusion region FD in the first pixel PXL1 from being disposed adjacent to the source of the source follower transistor SF and the source of the select transistor SEL of the second pixel PXL2.

A predetermined voltage may be applied to the shield SLD. In one or more example embodiments, a constant voltage (for example, a pixel power supply voltage, a ground voltage, or the like) may be applied to the shield SLD.

The shield SLD may be formed by doping impurities into the second semiconductor substrate 20, rather than forming an additional interconnection using a conductive material such as metal. The impurities of the shield SLD may have a conductivity type opposite to that of the impurities doped into the floating diffusion region FD. For example, when the impurity doped into the floating diffusion region FD has the second conductivity type, the impurity doped into the shield SLD may have the first conductivity type. The impurities having the first conductivity type impurity may be P-type impurities.

In one or more example embodiments, the shield SLD may have the same function as the shield SLD made of other metal interconnections (e.g. preventing coupling between two adjacent nodes). In addition, the shield SLD according to one or more example embodiments may effectively prevent coupling between components formed on the second semiconductor substrate 20 (e.g. node portions such as a source and/or a drain of each transistor and floating diffusion regions FDs implemented in an active region ACT of various nodes). Various components of the second semiconductor substrate 20 may be formed by doping the second semiconductor substrate 20 with impurities having various conductivity types, and extend to a certain depth within the second semiconductor substrate 20. Therefore, even when an additional metal interconnection is formed on the second semiconductor substrate 20, a shielding effect on the components within the second semiconductor substrate 20 is not significant. However, the shield SLD according to one or more example embodiments may be formed at a predetermined depth (e.g. at or beyond the certain depth of the components) within the second semiconductor substrate 20 to effectively prevent coupling of nodes implemented in the active region ACT.

The shield SLD may be provided between one or more floating diffusion regions FD1 and FD2 of the first pixel PXL1, and at least one of a source node and an output node of the source follower transistor SF of the second pixel PXL2. Alternatively or additionally, the shield SLD may be provided between one or more floating diffusion regions FD1 and FD2 of the second pixel PXL2, and at least one of a source node and an output node of the source follower transistor SF of the first pixel PXL1.

In one or more example embodiments, the shield SLD may extend in a column direction (e.g. the second direction D2) between the first pixel PXL1 and the second pixel PXL2 adjacent to each other. The shield SLD may have a bar shape elongated in the second direction D2. As illustrated, the shield may be provided in columns, separated between respective pixels PXL, including the first and second pixels PXL1 and PXL2.

In one or more example embodiments, the shield SLD may be provided in a portion of a region in which the third separation layer 253 is formed. The shield SLD may be provided in at least a portion, between first and second pixels PXL1 and PXL2 adjacent to each other, in the region in which the third separation layer 253 is provided. However, the region in which the shield SLD is provided is not limited thereto, and may be provided in a region that partially overlaps or does not overlap the third separation layer 253, regardless of a location of the third separation layer 253.

When parasitic capacitance or junction capacitance is formed between at least one of the source node and output node of the source follower transistor SF of the first pixel PXL1 and the floating diffusion regions FD of the second pixel PXL2, the voltage in the floating diffusion regions FD may fluctuate (e.g. drop) due to the parasitic capacitance or the junction capacitance. Such voltage fluctuations in the floating diffusion regions FD may ultimately cause ghost white spots in the image sensor output. In one or more example embodiments, the ghost white spots may be reduced by providing a shield SLD to prevent the formation of the parasitic capacitance or junction capacitance between at least one of the source node and output node of the source follower transistor SF of the second pixel PXL2 and the floating diffusion regions FD1 and FD2 of the first pixel PXL1.

The shield SLD according to one or more example embodiments may be provided between the first floating diffusion region FD1 and the output node to prevent coupling between the first floating diffusion region FD1 and the output node.

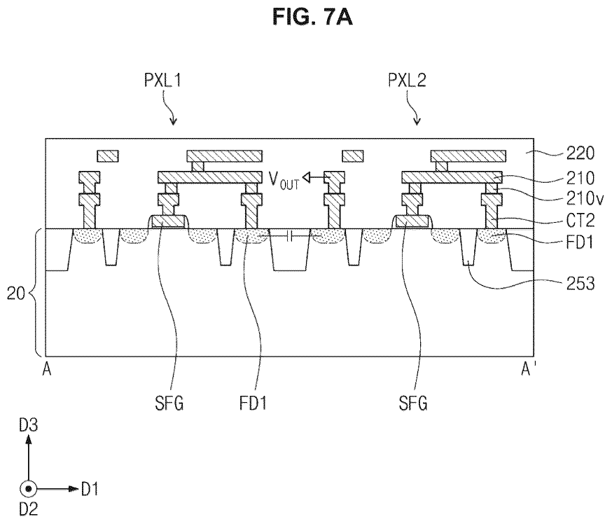

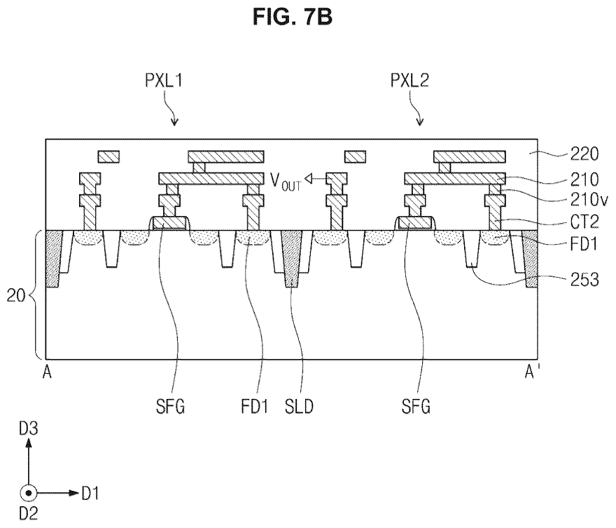

FIGS. 7A and 7B are cross-sectional views taken along line A-A′ of FIG. 5A and illustrate only a portion of the second structure. FIG. 7A is a cross-sectional view when the shield SLD is not provided, and FIG. 7B is a cross-sectional view when the shield SLD is provided.

Referring to FIG. 7A, the first floating diffusion region FD1 of the first pixel PXL1 and the output node of the second pixel PXL2 (e.g. a source of a select gate SG) may be disposed adjacent to each other when viewed in the plan view. Accordingly, the first floating diffusion region FD1 and the output node of the second pixel PXL2 may be coupled to form parasitic capacitance between the first floating diffusion region FD1 and the output node of the second pixel PXL2. Such parasitic capacitance may cause voltage fluctuation (e.g. voltage drop) in the first floating diffusion region FD1.

In contrast, referring to FIG. 7B, when a conductive shield SLD is provided between the first floating diffusion region FD1 and the output node of the second pixel PXL2, coupling between the first floating diffusion region FD1 and output nodes of the second pixel PXL2 may be prevented.

In FIGS. 7A and 7B, preventing coupling between the first floating diffusion region FD1 and the output node of the second pixel PXL2 (e.g. the source of the select gate SG) has been described, but example embodiments are not limited thereto and coupling between the first floating diffusion region FD1 and another node of the second pixel PXL2 may also be prevented. According to one or more example embodiments, coupling between the first floating diffusion region FD1 and the drain node of the select transistor SEL may be prevented by the shield SLD.

According to one or more example embodiments, not only coupling between the first floating diffusion region FD1 and the output node, but also coupling between the second floating diffusion region FD2 and other nodes may be prevented by the shield SLD.

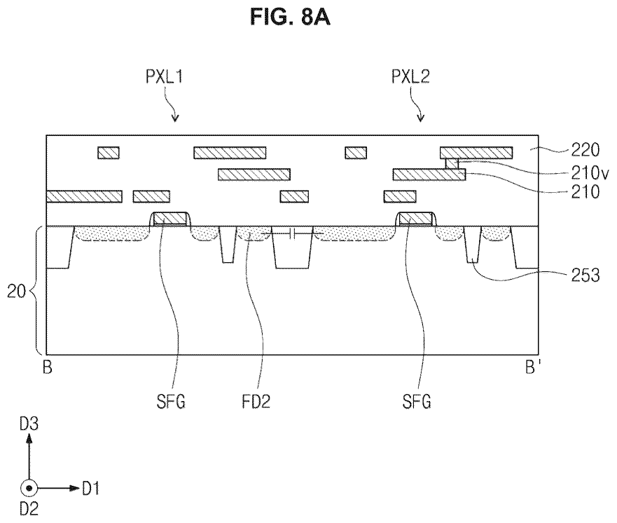

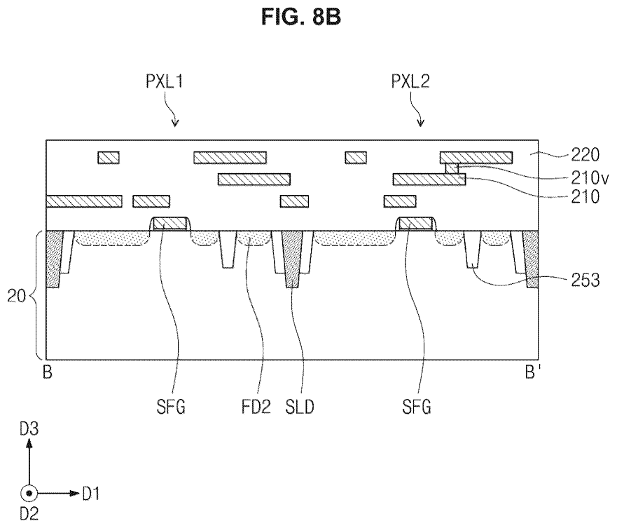

FIGS. 8A and 8B are cross-sectional views corresponding to line B-B′ of FIG. 5A and each illustrate only a portion of the second structure. FIG. 8A is a cross-sectional view when a shield SLD is not provided, and FIG. 8B is a cross-sectional view when a shield SLD is provided.

Referring to FIG. 8A, the second floating diffusion region FD2 of the first pixel PXL1 and the node of the second pixel PXL2 (e.g. a source of the source follower transistor SF or a drain of the select transistor SEL) may be adjacent to each other when viewed in plan view. Accordingly, the second floating diffusion region FD2 and the drain node of the select transistor SEL of the second pixel PXL2 may be coupled to form parasitic capacitance. Such parasitic capacitance may cause voltage fluctuation (e.g. voltage drop) in the second floating diffusion region FD2. In contrast, referring to FIG. 8B, a conductive shield SLD may be provided between the second floating diffusion region FD2 and the drain node of the select transistor SEL of the second pixel PXL2 to prevent coupling between the region FD1 and the drain node of the select transistor SEL.

In FIGS. 8A and 8B, preventing coupling between the second floating diffusion region FD2 of the first pixel PXL1 and the source node of the source follower transistor SF of the second pixel PXL2 has been described. Example embodiments are not limited thereto, and coupling between the second floating diffusion region FD2 of the first pixel PXL1 and another node of the second pixel PXL2 may be prevented by the shield SLD. For example, according to one or more example embodiments, coupling between the first floating diffusion region FD1 of the first pixel PXL1 and an output of the second pixel PXL2 may also be prevented by the shield SLD.

In the image sensor having the above-describes structure, the shield SLD may be provided between two adjacent pixels PXL to prevent coupling with the floating diffusion region FD, caused by nodes to which different signals are applied, and thus ghost white spots may be reduced.

In the image sensor according to one or more example embodiments, the shield SLD may be provided differently from the above-described embodiment. For example, the shield SLD according to one or more example embodiments may also be provided between two pixels adjacent to each other in the second direction D2 (e.g. the column direction). In this case, coupling between the first floating diffusion region FD1 and the pixel voltage node may be prevented.

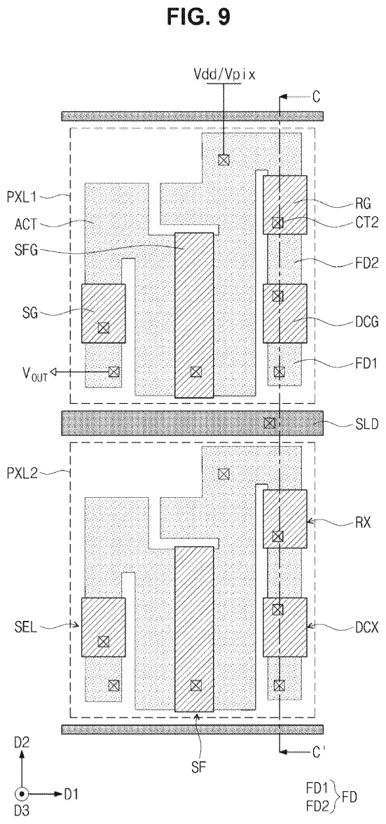

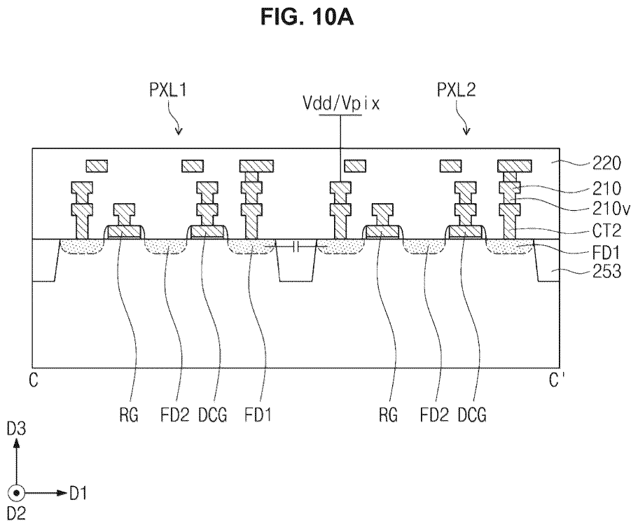

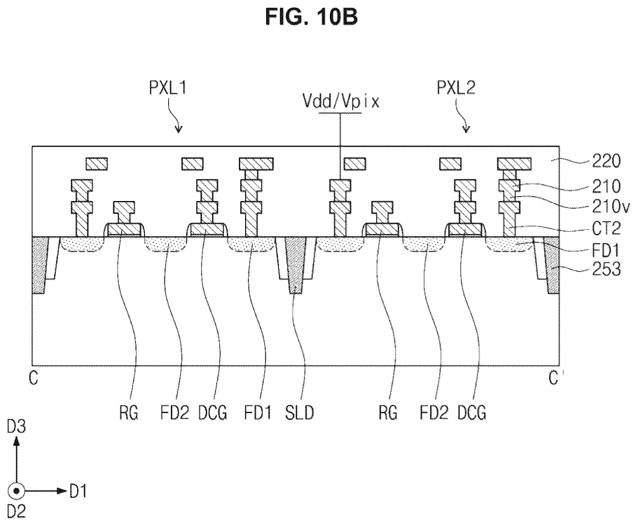

FIG. 9 is a diagram illustrating first and second pixels PXL1 and PXL2 adjacent to each other in a second direction D2 within an image sensor. FIGS. 10A and 10B are cross-sectional views taken along line C-C′ of FIG. 9A and each illustrate only a portion of a second structure. FIG. 10A is a cross-sectional view when the shield SLD is not provided, and FIG. 10B is a cross-sectional view when the shield SLD is provided.

Referring to FIGS. 9, 10A, and 10B, when two pixels adjacent to each other in the second direction D2 are referred to as a first pixel PXL1 and a second pixel PXL2, the shield SLD may also be provided between the first pixel PXL1 and the second pixel PX2 adjacent to the first pixel PXL1

In one or more example embodiments, the shield SLD may extend in the row direction (e.g. the first direction D1) between the first pixel PXL1 and the second pixel PXL2 adjacent to each other. The shield SLD may have a bar shape elongated in the first direction D1. As illustrated, the shield may be provided in rows, separated between respective pixels PXL, including the first and second pixels PXL1 and PXL2.

In the present embodiment(s), a first floating diffusion region FD1 of the first pixel PXL1 and the pixel voltage node (or the reset node) of the second pixel PXL2 are adjacent to each other in the plan view. For example, the first floating diffusion region FD1 of the first pixel PXL1 and the drain of a reset transistor RX or the drain of the source follower transistor SF of the second pixel PXL2 may be adjacent to each other in the plan view.

The first floating diffusion region FD1 of the first pixel PXL1 and the pixel voltage node of the second pixel PXL2 may be coupled to form parasitic capacitance. Such parasitic capacitance may cause voltage fluctuation (e.g. voltage drop) in the first floating diffusion region FD1 of the first pixel PXL1. In contrast, according to one or more example embodiments, a conductive shield SLD may be provided between the first floating diffusion region FD1 of the first pixel PXL1 and the pixel voltage node of the second pixel PXL2 to prevent coupling between the first floating diffusion region FD1 of the first pixel PXL1 and the pixel voltage node of the second pixel PXL2.

As described above, a shield according to one or more example embodiments may be provided in a column direction or a row direction between two adjacent pixels, among the plurality of pixels arranged in the matrix. However, the shape of the shield SLD is not limited thereto and may be modified in various ways.

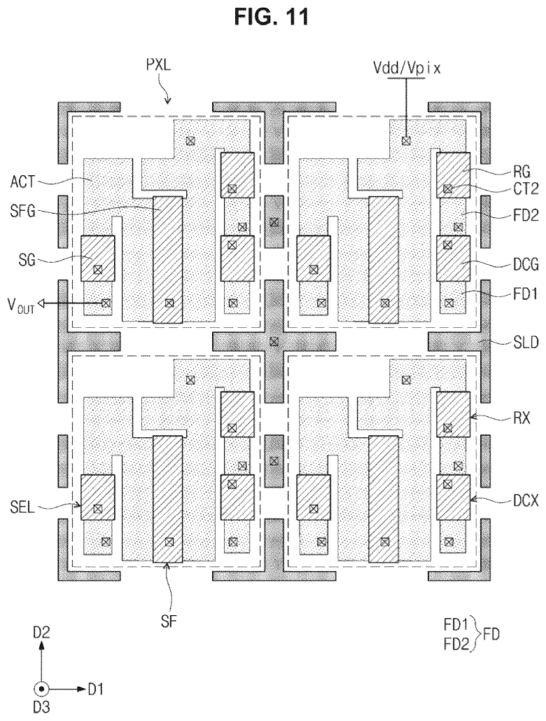

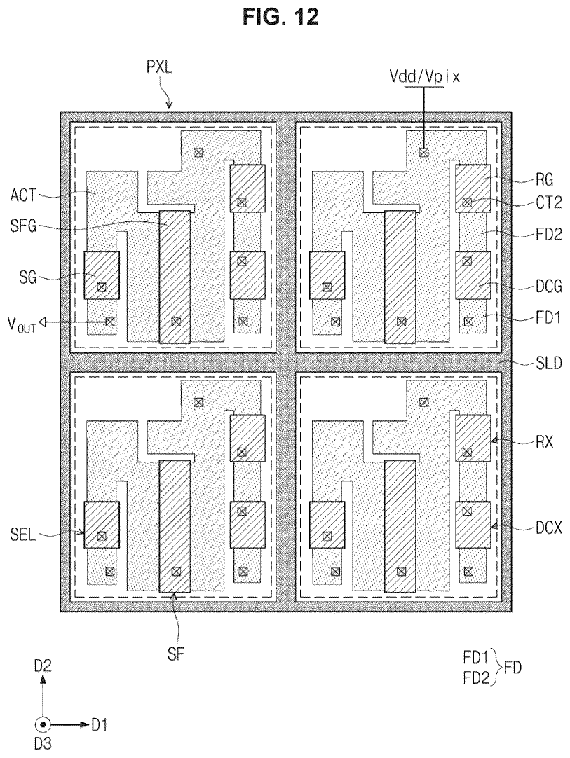

FIGS. 11 and 12 are diagrams, each illustrating that the shield SLD is formed to have a shape different from the shape in the above-described embodiments, in the image sensor according to one or more example embodiments.

Referring to FIG. 11, the shield SLD may be provided between two adjacent pixels PXL and may have an island shape. The island-shaped shield SLD may be provided in various numbers and in various locations. For example, the island-shaped shield SLD may be arranged to correspond to a location in which coupling occurs readily. For example, the shield SLD may be provided between the first floating diffusion region FD1 and/or the second floating diffusion region FD2 of the pixel PXL and nodes of other pixels PXL facing the first floating diffusion region FD1 and/or the second floating diffusion region FD2 of the above pixel PXL. In addition, the shield SLD may also be provided between two pixels PXL, adjacent to each other in a diagonal direction, to prevent coupling of the first floating diffusion region FD1 and/or the second floating diffusion region FD2 of a single pixel PXL to nodes of other pixels PXL disposed in an inclined direction rather than the row or column direction, for example the diagonal direction.

Referring to FIG. 12, the shield SLD may have a bar shape extending elongated in one direction. The elongated bar-shaped shield SLD may be disposed between pixels PXL in both the row direction and the column direction. Shields SLD disposed between adjacent pixels PXL may be connected to each other to form the grid shape. In this case, the shield SLD may be surround all pixels PXL. In this case, coupling between two adjacent pixels PXL may be more effectively prevented.

In one or more example embodiments, an additional shield SLD may be provided for nodes that may affect a voltage of the first floating diffusion region FD1 between two adjacent pixels PXL.

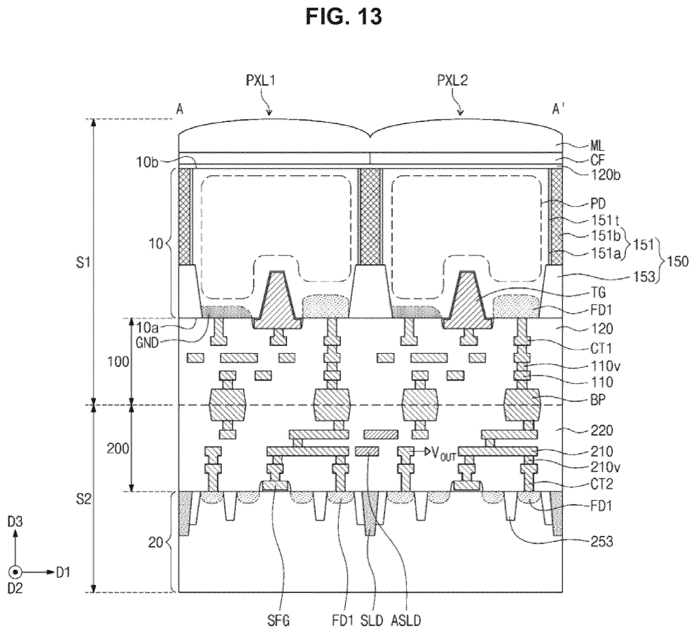

FIG. 13 is a cross-sectional view illustrating the image sensor according to one or more example embodiments. Differences between the following embodiments and the above-described embodiments will be described.

Referring to FIG. 13, second contacts CT2 connected to each transistor and one or more layers of second interconnections 210 directly or indirectly connected to the second contacts CT2 may be provided on the second semiconductor substrate 20. A portion of the second contacts CT2 and the second interconnections 210, for example, the second contact CT2 and second interconnections 210 connected to the first floating diffusion region FD1 may correspond to the same node as the first floating diffusion region FD1 (e.g. a first floating diffusion node). The first floating diffusion node may be coupled to other adjacent nodes. Such coupling may cause a fluctuation in voltage at the first floating diffusion node.

In one or more example embodiments, the image sensor may further include an additional shield ASLD, provided between the first floating diffusion node of one pixel PXL and nodes of another pixel PXL, between two adjacent pixels PXL. The additional shield ASLD may be provided between the first floating diffusion node of one pixel PXL (for example, the interconnection connected to at least one of the floating diffusion regions FD1) and nodes of another pixel PXL adjacent to the above pixel PXL (for example, at least one of the source node of the source follower transistor SF, the output node, and the pixel voltage node) to prevent coupling between the first floating diffusion node of the above pixel PXL and the nodes of the adjacent pixel PXL.

The additional shield ASLD may be applied with a constant voltage (for example, the pixel power supply voltage, the ground voltage, or the like).

The additional shield ASLD may include metal interconnections, and may be formed using the same material and the same process as other interconnections provided in the same layer.

The additional shield ASLD may be provided to prevent coupling between the first floating diffusion node and other nodes that may affect the first floating diffusion node. As a result, each pixel PXL may be driven more stably without the ghost white spot.

As described above, according to one or more example embodiments, the image sensor may include the shield SLD to prevent coupling between nodes which causes ghost white spots, resulting in improved quality of the image device.

In the above-described embodiments, an example has been described in which a portion of transistors of each pixel PXL are disposed on the first semiconductor substrate 10 of the first structure S1 and the remaining portion of the transistors are disposed on the second semiconductor substrate 20 of the second structure S2, but example embodiments are not limited thereto. Transistors of each pixel PXL may be provided on a semiconductor substrate of a single structure. In addition, a number of floating diffusion regions FD included in each pixel PXL, the type and number of transistors, and the nodes connected thereto may vary. For example, a single floating diffusion region FD, or three or more floating diffusion regions FD may be provided. The disclosure includes one or more example embodiments in which the shield SLD is formed between the floating diffusion region FD and nodes facing each other, even when locations of the floating diffusion region FD and the nodes are changed. Also, the disclosure includes one or more example embodiments in which the shield SLD is formed between the floating diffusion region FD and node facing each other even when a portion of the transistors are omitted.

As set forth above, the image sensor according to one or more example embodiments may prevent coupling between components in pixel circuits to reduce defects caused by the coupling.

In addition, the image sensor according to one or more example embodiments may prevent coupling between a floating diffusion region and another component and the white ghost spot caused by the coupling. As a result, a high-quality image sensor may be provided.

While certain example embodiments the disclosure have been particularly shown and described, it will be understood that various changes in form and details may be made therein without departing from the spirit and scope of the following claims.

What is claimed is:

1. An image sensor comprising:
a pixel array in which a plurality of pixels are arranged in a matrix, comprising a first pixel and a second pixel disposed adjacent to each other, each of the plurality of pixels comprising:
at least one photoelectric conversion device;
at least one floating diffusion region to which charges of the at least one photoelectric conversion device are configured to be transferred;
a reset transistor configured to transfer a voltage at a reset node to the at least one floating diffusion region;
a source follower transistor having one end connected to a pixel voltage node and configured to output a sampling voltage corresponding to the charges of the at least one floating diffusion region; and
a select transistor having one end connected to the source follower transistor and configured to output the sampling voltage to an output node, wherein a shield doped with an impurity is provided between the at least one floating diffusion region of the first pixel, and at least one of: a source node of the source follower transistor of the second pixel, the output node of the second pixel, and the pixel voltage node of the second pixel.

2. The image sensor of claim 1, wherein the shield is provided between the at least one floating diffusion region of the first pixel and the pixel voltage node of the second pixel.

3. The image sensor of claim 1, wherein the shield is a first region doped with a first impurity having a first conductivity type within a semiconductor substrate, and the at least one floating diffusion region is a second region doped with a second impurity having a second conductivity type, opposite to the first conductivity type, within the semiconductor substrate.

4. The image sensor of claim 3, wherein the semiconductor substrate is a silicon-based semiconductor substrate, a silicon-germanium-based semiconductor substrate, or a germanium semiconductor substrate.

5. The image sensor of claim 3, wherein the first conductivity type is P-type, and the second conductivity type is N-type.

6. The image sensor of claim 3, wherein the shield is configured to be applied with a constant voltage.

7. The image sensor of claim 3, wherein the shield is provided in a row direction of the matrix between the at least one floating diffusion region of the first pixel and the at least one of: the source node of the source follower transistor of the second pixel, the output node of the second pixel, and the pixel voltage node of the second pixel.

8. The image sensor of claim 3, wherein the shield is provided in a column direction of the matrix between the at least one floating diffusion region of the first pixel and the at least one of: the source node of the source follower transistor of the second pixel, the output node of the second pixel, and the pixel voltage node of the second pixel.

9. The image sensor of claim 3, wherein the shield is provided in a row direction and a column direction of the matrix between the at least one floating diffusion region of the first pixel and the at least one of: the source node of the source follower transistor of the second pixel, the output node of the second pixel, and the pixel voltage node of the second pixel.

10. The image sensor of claim 3, further comprising:
interconnections provided on the semiconductor substrate and directly or indirectly connected to the at least one of the source node of the source follower transistor of the second pixel, the output node of the second pixel, the pixel voltage node of the second pixel, and the at least one floating diffusion region of the first pixel.

11. The image sensor of claim 10, further comprising:
among the interconnections, an additional interconnection provided between a first interconnection connected to the at least one of the source node of the source follower transistor of the second pixel, the output node of the second pixel, and the pixel voltage node of the second pixel, and a second interconnection connected to the at least one floating diffusion region of the first pixel.

12. The image sensor of claim 1, wherein the at least one floating diffusion region of the first pixel is adjacent to the output node of the second pixel with the shield interposed therebetween.

13. The image sensor of claim 1, wherein the at least one floating diffusion region of the first pixel is adjacent to the source node of the source follower transistor of the second pixel with the shield interposed therebetween.

14. The image sensor of claim 1, wherein the shield is provided in an island shape.

15. The image sensor of claim 1, wherein the shield is provided in a bar shape extending to pixels adjacent to each other.

16. The image sensor of claim 1, wherein the shield is provided in a grid shape between pixels adjacent to each other.

17. The image sensor of claim 1, further comprising:
a first semiconductor substrate stacked with a second semiconductor substrate,
wherein the at least one photoelectric conversion device is provided on the first semiconductor substrate, and the at least one floating diffusion region, the reset transistor, the source follower transistor, and the select transistor are provided on the second semiconductor substrate.

18. An image sensor comprising:
a pixel array in which a plurality of pixels are arranged in a matrix,
wherein the plurality of pixels comprise a first pixel and a second pixel disposed adjacent to each other,
wherein each of the first pixel and the second pixel comprises at least one photoelectric conversion device, at least one floating diffusion region to which charges of the at least one photoelectric conversion device are configured to be transferred, a plurality of transistors, and a plurality of nodes, and
wherein a shield doped with an impurity is disposed between the at least one floating diffusion region of the first pixel and at least one of the plurality of transistors and the plurality of nodes of the second pixel.

19. The image sensor of claim 18, wherein the at least one floating diffusion region is a first region doped with a first impurity having a first conductivity type within a semiconductor substrate, and the shield is a second region doped with a second impurity having a second conductivity type, opposite to the first conductivity type, within in the semiconductor substrate.

20. An image sensor comprising:
a plurality of pixels arranged in a matrix; and
a plurality of stacked structures including a first structure and a second structure,
wherein each of the plurality of pixels comprises:
photoelectric conversion devices provided at one of the plurality of stacked structures; at least one floating diffusion region to which charges provided to the at least one of the plurality of stacked structures are configured to be transferred;
a plurality of transistors; and
a plurality of nodes,
wherein the at least one floating diffusion region, the plurality of transistors, and the plurality of nodes are provided in the first structure, and the photoelectric conversion devices are provided in the second structure, and
wherein a shield formed by doping an impurity into a semiconductor substrate is provided between two adjacent pixels of the plurality of pixels, and is configured to prevent coupling between the two adjacent pixels.
